(19) United States
(12) Patent Application Publication
(10) Pub. No.: US 2014/0055934 A1
(43) Pub. Date: Feb. 27, 2014

(54) SERVER

(71) Applicants: HONG FU JIN PRECISION INDUSTRY (ShenZhen) CO., LTD., (US); HON HAI PRECISION INDUSTRY CO., LTD., New Taipei (TW)

(72) Inventors: HUNG-YI WU, New Taipei (TW); HAN-BING ZHANG, Shenzhen (CN); LI-REN FU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,561

(22) Filed: Dec. 25, 2012

(30) Foreign Application Priority Data
Aug. 24, 2012 (CN) 2012103046737

(51) Int. Cl. H05K 7/14

(52) U.S. Cl. CPC H05K 7/1489
USPC 361/679.02

(57) ABSTRACT

A 2 unit (U) server includes a 2U chassis, two system modules, and two power supply units. The chassis includes a bottom plate, two side plates, a cover, and a middle plate arranged between the side plates in parallel. A supporting plate is connected between rear ends of the middle plate and each side plate. A distance between each supporting plate and the cover, and a distance between each supporting plate and the bottom plate is the same, being equal to 1U. A space between the middle plate and each side plate receives one of the system modules. A height of a front end of each system module is 2U. A height of a rear end of each system module is 1U. The rear end of each system module is received between the bottom plate and one of the supporting plates. Each supporting plate supports a power supply unit.

### BACKGROUND

1. Technical Field

The present disclosure relates to a 2 unit (U) server.

2. Description of Related Art

Rack servers are usually grouped into 1U, 2U, and 4U systems, wherein the “U” designation refers to a dimensional increment of 1.75 inches in height along the vertical members of an Electronics Industry Alliance (EIA) industry-standard computer racking/mounting structure. Typically, a 2U server includes a plurality of 1U system modules installed therein. However, those 1U system modules cannot receive elements higher than 1U.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a 2 unit server.

FIG. 2 is a partially assembled, isometric view of the 2 unit server of FIG. 1 from another perspective.

FIG. 3 is an assembled, isometric view of the 2 unit server of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

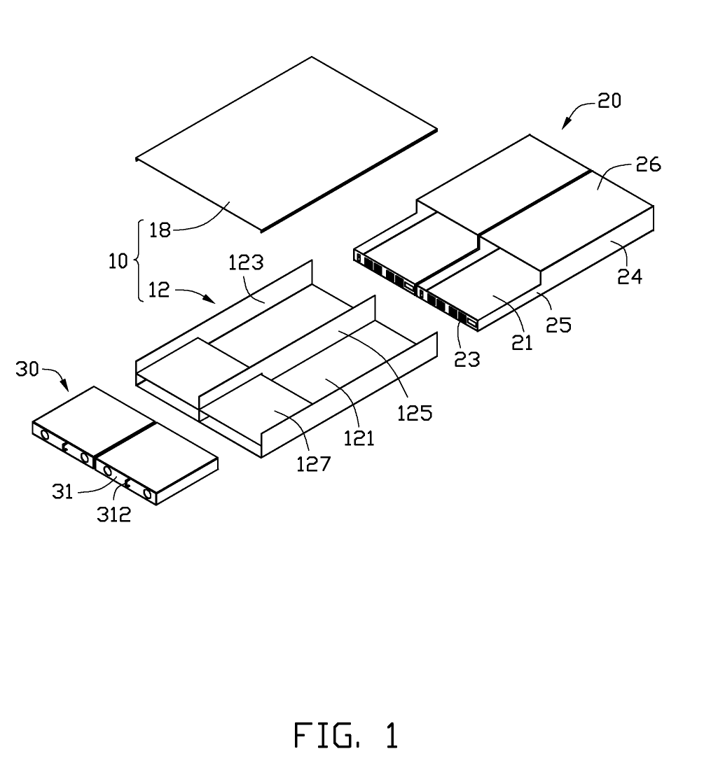

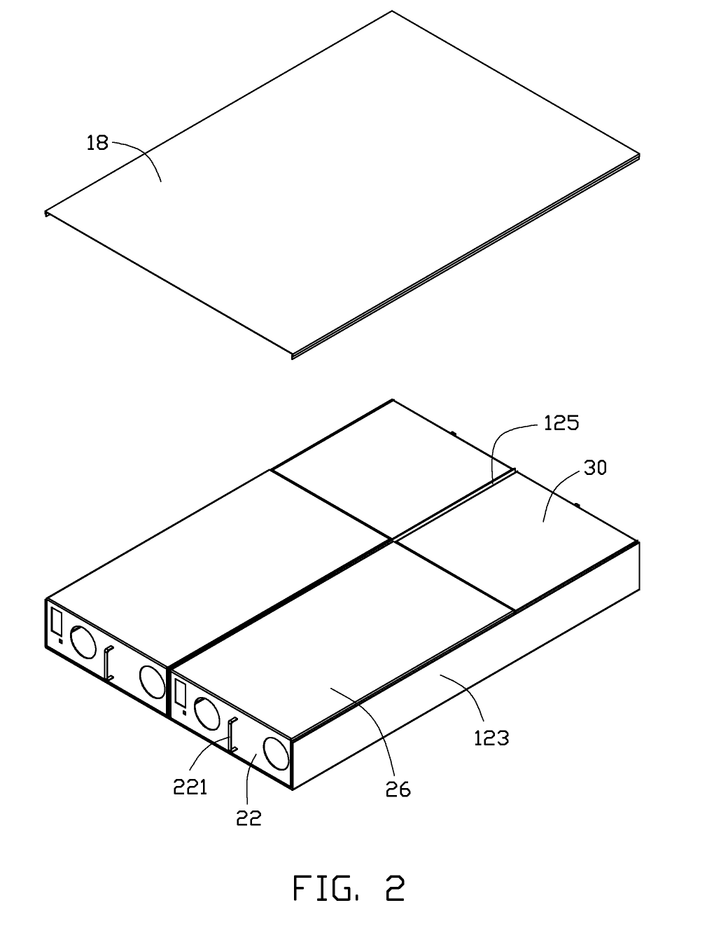

FIGS. 1 and 2 show an embodiment of a 2 unit (U) server. The 2U server includes a chassis 10 with a height of 2U, two system modules 20, and two power supply units 30.

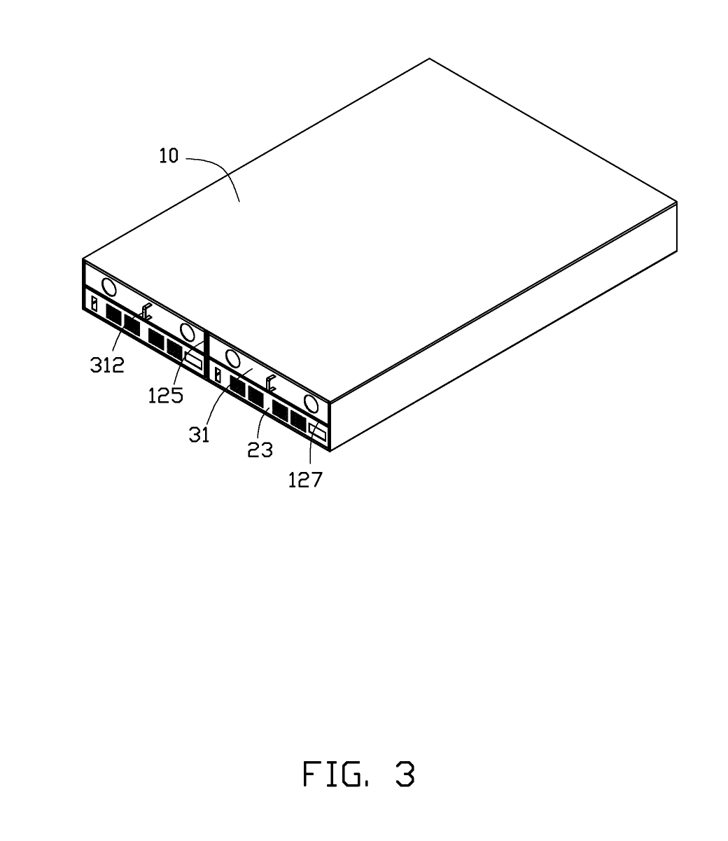

The chassis 10 includes a base 12 and a cover 18. The base 12 includes a bottom plate 121 and two side plates 123 extending upward from opposite sides of the bottom plate 121 in a substantially perpendicular manner. A middle plate 125 parallel to the side plates 123 extends upward from a middle of the bottom plate 121, between the side plates 123. A supporting plate 127 is perpendicularly connected between the middles of the rear ends of the middle plate 125 and each side plate 123. FIG. 3 shows that the cover 18 covers the base 12. A distance between each supporting plate 127 and the cover 18, and a distance between each supporting plate 127 and the bottom plate 121 are both equal to 1U.

Each system module 20 includes a bottom wall 21, a first end wall 22 with a height of 2U extending upward from the front end of the bottom wall 21, a second end wall 23 with a height of 1U extending upward from the rear end of the bottom wall 21, two first sidewalls 24 with a height of 2U extending upward from the front ends of opposite sides of the bottom wall 21, two second sidewalls 25 with a height of 1U extending upward from the rear ends of the opposite sides of the bottom wall 21, and a top wall 26 perpendicularly connected between the tops of the first sidewalls 24. The front end of each second sidewall 25 is connected to the lower half of the rear end of the corresponding first sidewall 24. A length of each second sidewall 25 is equal to a length of each supporting plate 127. A handle 221 is mounted to an outer surface of each first end wall 22.

A height of each power supply unit 30 is not more than 1U, and a length of each power supply unit 30 is not more than the length of each supporting plate 127. Each power supply unit 30 includes a rear end wall 31, and a handle 312 is mounted to an outer surface of each rear end wall 31.

FIGS. 2 and 3 show that in assembly, the cover 18 covers the base 12. The two system modules 20 are inserted into the chassis 10 from the front end of the chassis 10, to allow each system module 20 to be received between the middle plate 125 and one of the side plates 123. The tops of the second sidewalls 25 of each system module 20 are covered by a supporting plate 127. The front ends of the supporting plates 127 abut the rear ends of the first sidewalls 24 of the system modules 20. The two power supply units 30 are inserted into the chassis 10 from the rear end of the chassis 10, each supporting plate 127 supports one of the power supply units 30. The handles 221 extend out of the front end of the chassis 10, and the handles 312 extend out of the rear end of the chassis 10, allowing a user to pull the system modules 20 and the power supply units 30 out from the chassis 10.

The height of the first sidewalls 24 of each system module 20 is 2U, to allow a space between the first sidewalls 24 of the system module 20 to receive elements which are higher than 1U but lower than 2U, such as heat sinks. The height of the second sidewalls 25 of each system module 20 is 1U, to allow a space between the second sidewalls 25 of the system module 20 to receive elements lower than 1U, and to vacate the higher half of the rear end of the chassis 10 above the supporting plates 127, for receiving the power supply units 30.

In other embodiments, a plurality of middle plates 125 parallel to the side plates 123 are mounted in the chassis 10, to receive a plurality of system modules 20 which are less wide. A supporting plate 127 is connected between the rear ends of every two adjacent middle plates 125, and a supporting plate 127 is connected between the rear ends of each side plate 123 and a middle plate 125 adjacent to the side plate 123, to receive a plurality of power supply units 30 of less width in the chassis 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A 2 unit (U) server, comprising:
a chassis with a height of 2U comprising a bottom plate, two opposite side plates perpendicular to the bottom plate, a cover covering the side plates, and a middle plate arranged between the side plates and parallel to the side plates, wherein a supporting plate is perpendicularly connected between rear ends of the middle plate and each side plate, a distance between each supporting plate and the cover, and a distance between each supporting plate and the bottom plate are both equal to 1U;
two system modules, wherein a space between the middle plate and each side plate receives one of the system modules, a height of a front end of each system module is 2U, and a height of a rear end of each system module is 1U, the rear end of each system module is received between the bottom plate and one of the supporting plates; and
two power supply units with height not more than 1U, wherein each supporting plate supports a power supply unit.

2. The 2U server of claim 1, wherein each system module comprises a bottom wall, a first end wall with a height of 2U extending upward from a front end of the bottom wall, a second end wall with a height of 1U extending upward from a rear end of the bottom wall, two first sidewalls with a height of 2U extending upward from front ends of opposite sides of the bottom wall, and two second sidewalls with a height of 1U extending upward from rear ends of the opposite sides of the bottom wall, the front end of each second sidewall is connected to a lower half of a rear end of a corresponding one of the first sidewalls.

3. The 2U server of claim 2, wherein a handle is mounted to an outer surface of each first end wall, extending out of a front end of the chassis.

4. The 2U server of claim 2, wherein each system module further comprises a top wall perpendicularly connected between tops of the first sidewalls of the system module.

5. The 2U server of claim 2, wherein a length of each second sidewall is equal to a length of each supporting plate.

6. The 2U server of claim 5, wherein a length of each power supply unit is not more than a length of each supporting plate.

7. The 2U server of claim 1, wherein each power supply unit comprises a rear end wall, and a handle is mounted to an outer surface of each rear end wall, extending out of a rear end of the chassis.

8. A 2 unit (U) server, comprising:
a chassis with a height of 2U comprising a bottom plate, two opposite side plates perpendicular to the bottom plate, a cover covering the side plates, and a plurality of middle plates arranged between the side plates and parallel to the side plates, wherein a supporting plate is perpendicularly connected between rear ends of every two adjacent middle plates, and a supporting plate is perpendicularly connected between rear ends of each side plate and a corresponding one of the middle plates adjacent to the side plate, a distance between each supporting plate and the cover, and a distance between each supporting plate and the bottom plate are both equal to 1U;
a plurality of system modules, wherein a space between every two adjacent middle plates receives one of the system modules, and a space between each side plate and the corresponding middle plate adjacent to the side plate receives one of the system modules, a height of a front end of each system module is 2U, and a height of a rear end of each system module is 1U, the rear end of each system module is received between the bottom plate and one of the supporting plates; and
a plurality of power supply units with height not more than 1U, wherein each supporting plate supports one of the power supply units.

9. The 2U server of claim 8, wherein each system module comprises a bottom wall, a first end wall with a height of 2U extending upward from a front end of the bottom wall, a second end wall with a height of 1U extending upward from a rear end of the bottom wall, two first sidewalls with a height of 2U extending upward from front ends of opposite sides of the bottom wall, and two second sidewalls with a height of 1U extending upward from rear ends of the opposite sides of the bottom wall, the front end of each second sidewall is connected to a lower half of a rear end of a corresponding one of the first sidewalls.

10. The 2U server of claim 9, wherein a handle is mounted to an outer surface of each first end wall, extending out of a front end of the chassis.

11. The 2U server of claim 9, wherein each system module further comprises a top wall perpendicularly connected between tops of the first sidewalls of the system module.

12. The 2U server of claim 9, wherein a length of each second sidewall is equal to a length of each supporting plate.

13. The 2U server of claim 12, wherein a length of each power supply unit is not more than the length of each supporting plate.

14. The 2U server of claim 8, wherein each power supply unit comprises a rear end wall, and a handle is mounted to an outer surface of each rear end wall, extending out of a rear end of the chassis.
